(19) United States
(12) Patent Application Publication
(10) Pub. No.: US 2025/0210485 A1
(43) Pub. Date: Jun. 26, 2025

(54) COMPOSITE SUBSTRATE AND MANUFACTURING METHOD OF THE SAME AND COMMUNICATION DEVICE

(71) Applicant: AUO Corporation, Hsinchu (TW)

(72) Inventors: Shih-Hsien Yang, Hsinchu (TW); Yi-Cheng Lai, Hsinchu (TW); Chung-Hung Chen, Hsinchu (TW); Yu-Chih Wang, Hsinchu (TW); Yi-Hui Lin, Hsinchu (TW); Shuo-Yang Sun, Hsinchu (TW); Zong-Long Jhang, Hsinchu (TW)

(73) Assignee: AUO Corporation, Hsinchu (TW)

(21) Appl. No.: 18/399,709

(22) Filed: Dec. 29, 2023

(30) Foreign Application Priority Data
Dec. 22, 2023 (TW) 112150317

(51) Int. Cl. H01L 23/498; H01L 21/48; H01L 23/00; H01L 25/065; H01Q 1/22

(52) U.S. Cl. CPC H01L 23/49822; H01L 21/4857; H01L 21/486; H01L 23/49838; H01L 24/16; H01L 25/0655; H01Q 1/2283; H01L 24/13; H01L 24/32; H01L 24/73; H01L 2224/13005; H01L 2224/16227; H01L 2224/32225; H01L 2224/73204

(57) ABSTRACT

A communication device includes a plurality of dies, a composite substrate and at least one antenna. The composite substrate includes a PCB, a redistribution layer and a connecting layer. The connecting layer is configured to electrically connect the redistribution layer and the PCB. Each die is electrically connected to the redistribution layer. The distribution layer corresponding to each die is formed integrally. The PCB is disposed between the antenna and the redistribution layer. The antenna is electrically connected to the dies through the composite substrate. A manufacturing method of the composite substrate is also provided.

### CROSS-REFERENCE TO RELATED APPLICATION

This application claims the priority benefit of Taiwan application serial no. 112150317, filed on Dec. 22, 2023. The entirety of the above-mentioned patent application is hereby incorporated by reference herein and made a part of this specification.

### BACKGROUND

### Technical Field

The present disclosure relates to an electronic component and a manufacturing method thereof, and in particular to a composite substrate, a manufacturing method thereof, and a communication device.

### Description of Related Art

In recent years, a lot of studies have been carried out on 5G millimeter wave communications proactively, wherein the studies and development on antenna modules play an important role. In the conventional method, after a die is packaged, the die is then bonded to a printed circuit board. However, the base of the printed circuit board is glass fiber, and the dielectric constant thereof is unstable, which will affect the performance of the antenna and cause the impedance of the transmission line to be unstable. In addition, in the process of manufacturing printed circuit boards, the inner layer circuits need to be blackened and browned before being laminated to increase the adhesion between layers, copper wires and dielectric layers. Apart from causing the printed circuit board to warp and the copper wire to break, such a process will also increase the roughness of the copper wire and increase transmission loss. Moreover, the cost of chip packaging is high, and the size of chip becomes larger after packaging, which also causes the increase of the length of the signal transmission path during use and increases loss.

### SUMMARY

The present disclosure provides a composite substrate, a manufacturing method thereof, and a communication device. Compared with conventional PCB, the number of glass fiber layers in the composite substrate is less. The communication device manufactured by including the composite substrate has a lower price and less transmission loss.

According to an embodiment of the present disclosure, a composite substrate is provided, which is suitable for connecting multiple dies. The composite substrate includes a printed circuit board, a redistribution layer and a connecting layer. The redistribution layer is disposed on the printed circuit board. The connecting layer is disposed to electrically connect the redistribution layer and the printed circuit board. Each die is electrically connected to the redistribution layer, and is integrally disposed with the redistribution layer corresponding to each die.

According to another embodiment of the present disclosure, a communication device is provided, including a plurality of dies, a composite substrate and at least one antenna. The composite substrate includes a printed circuit board, a redistribution layer and a connecting layer. The redistribution layer is disposed on the printed circuit board. The connecting layer is disposed to connect the redistribution layer and the printed circuit board. Each die is electrically connected to the redistribution layer, and is integrally disposed with the redistribution layer corresponding to each die. The printed circuit board is disposed between the antenna and the redistribution layer, and the antenna is electrically connected to the dies through the composite substrate.

According to yet another embodiment of the present disclosure, a method for manufacturing a composite substrate is provided, including disposing a transparent substrate;

forming at least one redistribution layer on the transparent substrate; disposing a connecting layer on the redistribution layer; and disposing a printed circuit board on the connecting layer; removing the transparent substrate to form a stacked structure; forming a first metal layer on one side of the stacked structure close to the redistribution layer, and forming a second metal layer on the other side of the stacked structure close to the printed circuit board; forming a through hole in the stacked structure; disposing a third metal layer on the sidewall of the through hole; and performing photolithography and etching processes on the first metal layer and the second metal layer to form a first circuit layer and a second circuit layer respectively, wherein the first circuit layer and the second circuit layer are at least partially electrically connected to the third metal layer.

Based on the above, the composite substrate provided by the embodiment of the present disclosure is adaptable for connecting unpackaged dies, thereby significantly reducing the manufacturing cost of communication devices, effectively shortening the transmission path of signals, and reducing transmission loss. Moreover, the transmission path of signals is on the redistribution layer with low DK and DF. The surface roughness of the metal wiring layer of the redistribution layer is low, which not only reduces transmission loss, but also decreases the difficulty in design of input impedance matching.

In order to make the above-mentioned features and advantages of the present disclosure more comprehensible, embodiments are given below and described in detail with reference to the attached drawings.

### BRIEF DESCRIPTION OF THE DRAWINGS

FIG. 1A to FIG. 1F are schematic diagrams of a manufacturing method of a composite substrate according to an embodiment of the present disclosure.

FIG. 1G is a schematic diagram illustrating the application of composite substrate according to an embodiment of the present disclosure.

FIG. 2 is a schematic diagram of a communication device according to an embodiment of the present disclosure.

FIG. 3 is a schematic diagram of a communication device according to an embodiment of the present disclosure.

FIG. 4 is a partial structural diagram of an electronic device according to a comparative example.

### DESCRIPTION OF THE EMBODIMENTS

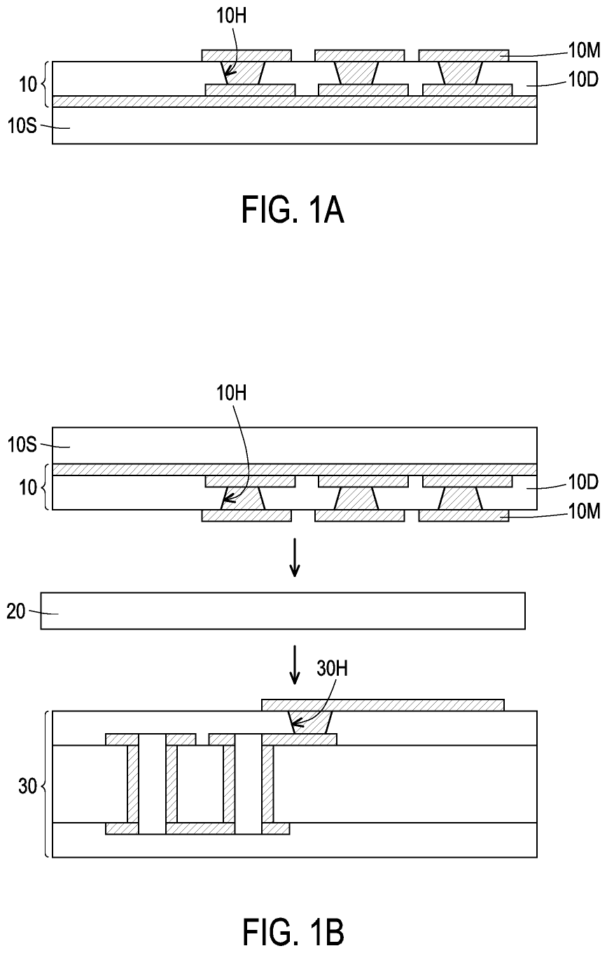

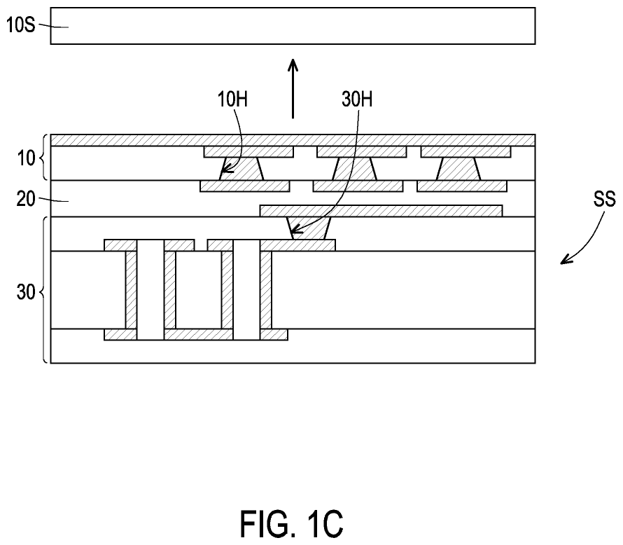

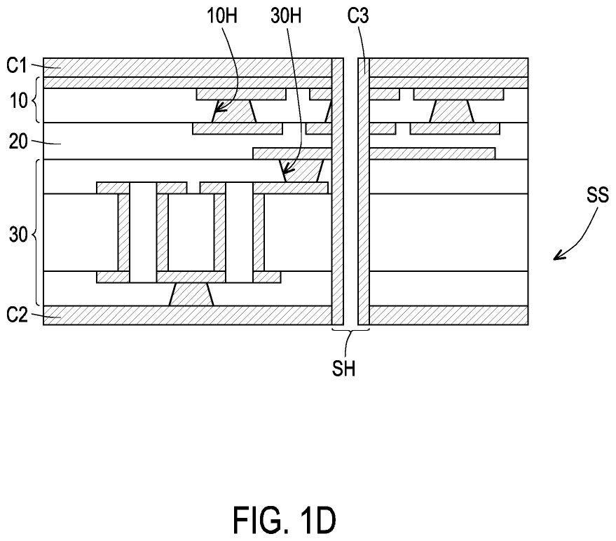

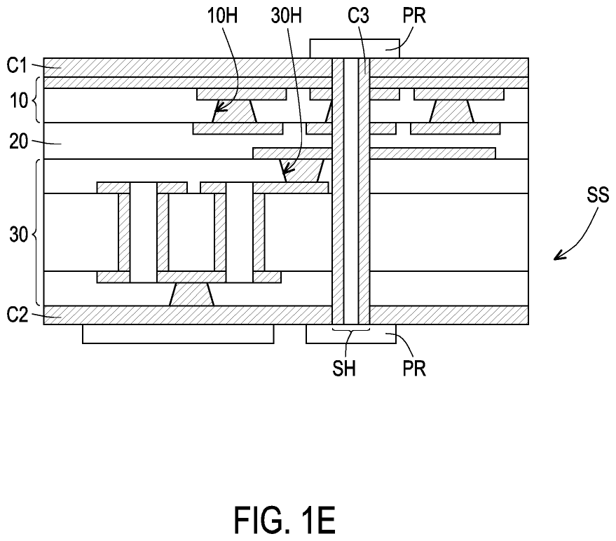

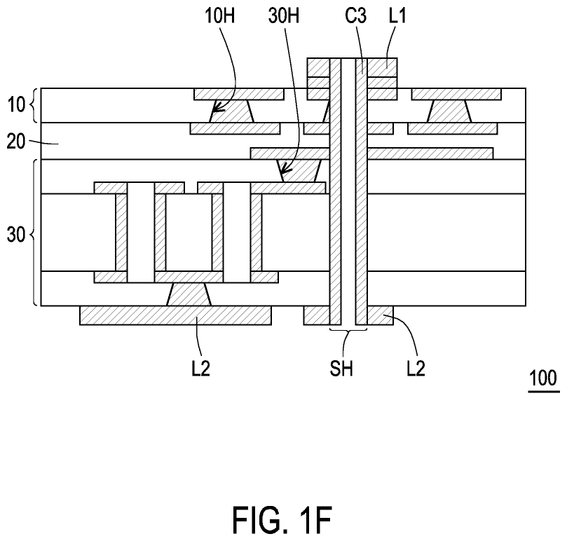

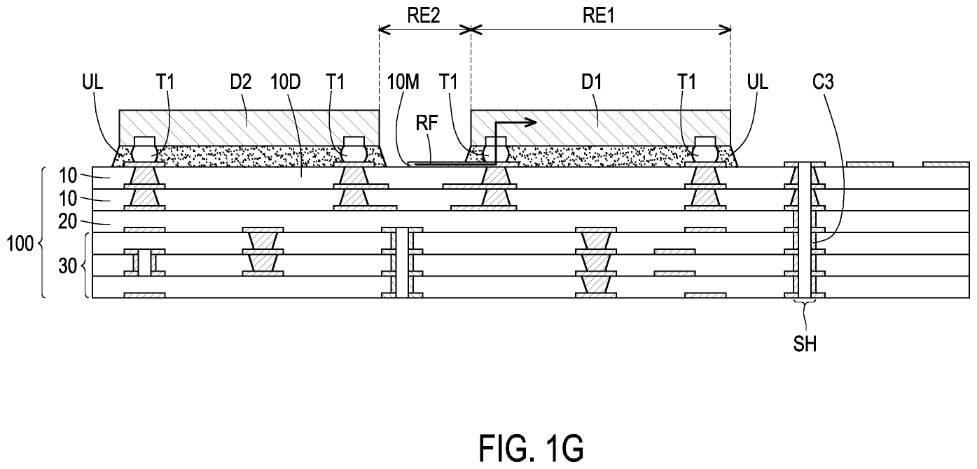

According to an embodiment of the present disclosure, please refer to FIG. 1A to FIG. 1F, which provide a manufacturing method of a composite substrate. FIG. 1A to FIG. 1F are for illustrative purposes only, are not drawn to scale, and some structures, layers, or geometries may be omitted.

Referring to FIG. 1A, first, a redistribution layer 10 is formed on a transparent substrate 10S, wherein the redistribution layer 10 includes a patterned dielectric layer 10D and a patterned metal wiring layer 10M. The metal wiring layer 10M may include one of copper, aluminum, nickel, gold, silver and titanium or a combination of two of the above.

Referring to FIG. 1B, a connecting layer 20 is then disposed on the redistribution layer 10, and then the printed circuit board 30 is disposed on the connecting layer 20. The connecting layer 20 may be, for example, a low-loss sheet-like adhesive layer. Specifically, the redistribution layer 10 may be turned over to face the connecting layer 20, and then the printed circuit board 30 and the redistribution layer 10 may be pasted on the connecting layer 20 respectively. One surface of the connecting layer 20 may be pasted to the redistribution layer 10 first, and then the other surface of the connecting layer 20 may be pasted to the printed circuit board 30. In some embodiments, the connecting layer 20 may have thermoplastic or thermoset properties, and the connecting layer 20 may be heated.

Referring to FIG. 1C, the transparent substrate 10S is then removed to form a stacked structure SS formed by the redistribution layer 10, the connecting layer 20 and the printed circuit board 30 stacked in sequence.

Referring to FIG. 1D, a metal layer C1 is formed on one side of the stacked structure SS close to the redistribution layer 10, and a metal layer C2 is formed on one side of the stacked structure SS close to the printed circuit board 30. For example, mechanical drilling is performed to form a through hole SH in the stacked structure SS, and a metal layer C3 is disposed on the sidewall of the through hole SH by, for example, electroplating. In some embodiments, the metal layers C1, C2, and C3 may be implemented by a layer including one of copper, aluminum, nickel, gold, silver, and titanium or a combination of two of the above.

Referring to FIG. 1E and FIG. 1F, a photoresist PR is then applied, and the metal layer C1 and the metal layer C2 are subjected to photolithography and etching processes to form the circuit layer L1 and the circuit layer L2 respectively, wherein the circuit layer L1 and the circuit layer L2 are at least partially and electrically connected to the metal layer C3. The composite substrate 100 is completed according to the steps shown in FIG. 1A to FIG. 1F. Since the redistribution layer 10 is first flipped and then pasted to the connecting layer 20 in the step shown in FIG. 1B, the redistribution layer 10 in the composite substrate 100 has a through hole 10H that is narrow at the top and wide at the bottom, and the printed circuit board 30 in the composite substrate 100 has a through hole 30H that is wide at the top and narrow at the bottom. That is to say, in the stacking direction of the composite substrate 100 (the upward direction in FIG. 1F), the width of the through hole 30H of the printed circuit board 30 gradually becomes larger, and the width of the through hole 10H of the redistribution layer 10 gradually becomes smaller.

Next, please refer to FIG. 1G, which schematically illustrates the application of the composite substrate according to an embodiment of the present disclosure. The composite substrate 100 includes a printed circuit board 30, a plurality of redistribution layers 10 and a connecting layer 20. The redistribution layers 10 are disposed on the printed circuit board 30 and each includes a patterned dielectric layer 10D and a patterned metal wiring layer 10M. The connecting layer 20 may be, for example, a low-loss sheet-like adhesive layer, an anisotropic conductive film (ACF), or a connecting layer using Cu-Cu hybrid bonding technology. The printed circuit board 30 and the redistribution layers 10 are adhered together, and the redistribution layers 10 and the printed circuit board 30 are electrically connected through the metal layer C3 on the through hole SH.

The composite substrate 100 is suitable for connecting multiple dies D1 and D2. Both dies D1 and D2 are electrically connected to the redistribution layer 10. It is worth mentioning that since each redistribution layer 10 is entirely attached to the printed circuit board 30, the redistribution layer 10 connected to the dies D1 and the redistribution layer 10 connected to the dies D2 are the same redistribution layer 10 disposed in an integrated manner.

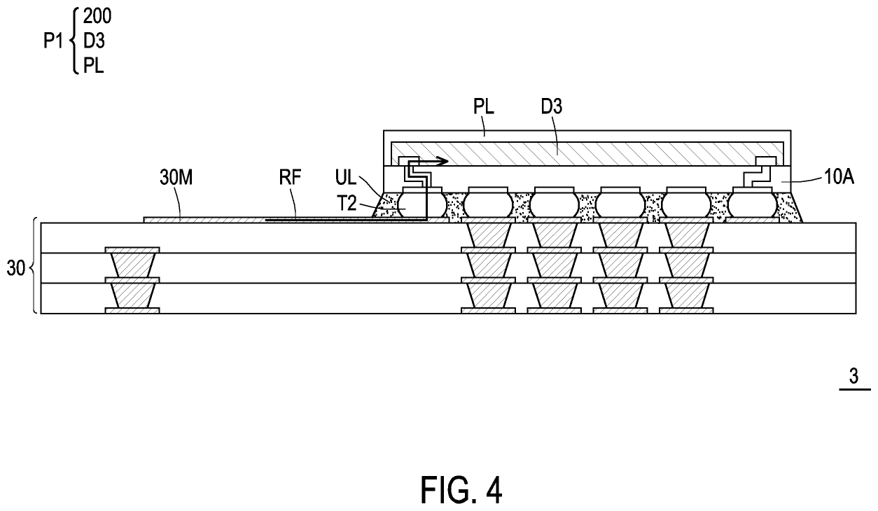

In the redistribution layer 10, the metal line width of the metal wiring layer 10M that does not correspond to each die D1 and D2 is greater than 50 microns. In contrast, the metal wiring layer 10M corresponding to each die D1 and D2 may have a smaller metal line width (the line width falls within the range of 3 microns to 50 microns). Specifically, the metal line width of the metal wiring layer 10M not located under each die D1 and D2 (corresponding to the area RE2 in FIG. 1G) is greater than 50 microns, and the metal line width of the metal wiring layer 10M located under each die D1 and D2 (corresponding to the area RE1 in FIG. 1G) falls within the range of 3 microns to 50 microns. Accordingly, the size of the solder bump T1 connected between dies D1 and D2 and the redistribution layer 10 may be smaller, and the diameter may fall within the range of 10 microns to 200 microns. In contrast, please refer to FIG. 4, which schematically illustrates a partial structural diagram of an electronic device according to a comparative example. The electronic device 3 may be implemented as a communication device 3, for example, and includes a printed circuit board 30 and a chip package P1, wherein the chip package P1 is connected to the printed circuit board 30 through a plurality of solder bumps T2. The chip package P1 includes a die D3, an in-chip redistribution layer 10A and a packaging layer PL. Due to the large metal line width (greater than 50 microns) in the printed circuit board 30, the size of the solder bump T2 is larger than the solder bump T1 in FIG. 1G, and the diameter approximately falls within the range of 200 microns to 500 microns.

Refer to FIG. 4 and FIG. 1G simultaneously. In FIG. 4, when the signal RF is input from the signal input terminal in the communication device 3, the signal RF will reach the die D3 after sequentially passing through the copper wire 30M on the surface of the printed circuit board 30, the solder bump T2, and the in-chip redistribution layer 10A. In contrast, in FIG. 1G, when the signal RF is input from the signal input terminal of the composite substrate 100, the signal RF will reach the die D1 (or die D2) after passing through the metal wiring layer 10M of the redistribution layer 10 and the solder bump T1. The signal RF does not need to pass through the printed circuit board 30 underneath the redistribution layer 10. That is to say, compared with the conventional communication device 3, the composite substrate 100 provided according to the embodiment of the present disclosure may effectively shorten the transmission path of signals and reduce the transmission loss.

Further, the base of the printed circuit board 30 is glass fiber, and the dielectric constant thereof is unstable. In contrast, the material of the dielectric layer 10D of the redistribution layer 10 may include, for example, one of epoxy resin, silicone, PI, PBO, BCB, silicon oxide, phosphosilicate glass, and fluorine-containing glass or a combination of the two of the above, and the dielectric constant thereof is more stable than glass fiber. Specifically, the DK value and DF value of the printed circuit board 30 are approximately 3.0 to 4.0 and 0.0027 to 0.0037 respectively, and the DK value and DF value of the dielectric layer 10D of the redistribution layer 10 are approximately 2.5 to 3.0 and 0.001 to 0.0025 respectively. Therefore, when the transmission path of the signal RF in the composite substrate 100 provided by the embodiment of the present disclosure is on the redistribution layer 10 instead of the printed circuit board 30, the transmission loss may be further reduced due to the characteristics of low DK and DF of the redistribution layer 10.

It should also be noted that in the process of manufacturing the printed circuit board 30, the conductive copper wires thereof need to be blackened and browned before they can be laminated to increase the grip strength between the layers and between the copper wire and dielectric layer. Apart from causing the printed circuit board 30 to warp and the copper wires to break, such a process will also increase the surface roughness of the copper wires in the printed circuit board 30 by 3.2 microns approximately, resulting in uneven distribution of the electric field on the surface of the copper wires and increasing the transmission loss of the signal RF, and affecting the input impedance matching, which causes design difficulties. In contrast, the composite substrate 100 provided according to the embodiment of the present disclosure utilizes the metal wiring layer 10M of the redistribution layer 10 to transmit the signal RF, and the redistribution layer 10 does not need to be blackened and browned like the printed circuit board 30. Therefore, the metal wiring layer 10M may have a lower surface roughness which significantly reduces transmission loss of the signal RF. Specifically, the roughness of the metal wiring layer 10M of the composite substrate 100 provided according to the embodiment of the present disclosure generally falls within the range of 0.2 microns to 0.7 microns. That is to say, the ratio of the roughness of the copper wires of the printed circuit board 30 to the roughness of the metal wiring layer 10M generally falls within the range of 4.5 to 16. Moreover, since there is a small difference in surface roughness of different parts of the metal wiring layer 10M, the difficulty in the design of input impedance matching is reduced.

In addition to the above-mentioned differences in shortening the transmission path of the signal RF, the characteristics of low DK and DF of the redistribution layer 10, and the roughness of the metal wiring layer 10M being less than the roughness of the copper wires in the printed circuit board 30, the overall size of the chip package P1 in FIG. 4 will be greater than the sizes of dies D1 and D2 in FIG. 1G. For example, the thickness of chip package P1 is about 280 microns to 400 microns, and the thickness of the dies D1 and D2 is about 200 microns to 250 microns. Accordingly, the size of the device using the composite substrate 100 (e.g., the communication device 1 or the communication device 2 described below) may be further reduced.

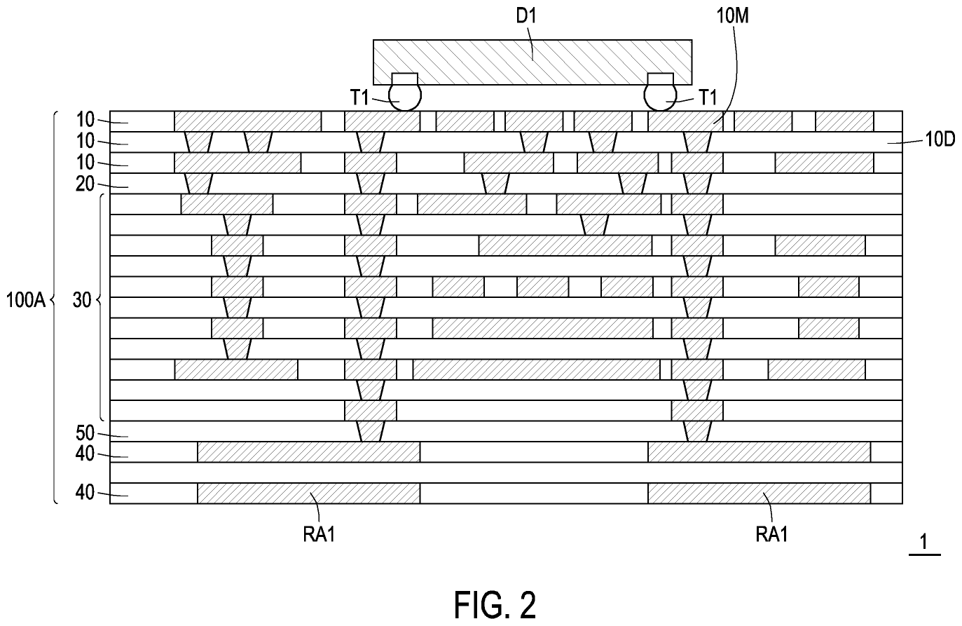

Referring to FIG. 2, according to an embodiment of the present disclosure, a communication device 1 is provided, including a plurality of dies D1, a composite substrate 100A and an antenna RA1. For the purpose of illustration, FIG. 2 only shows a partial structure of the communication device 1 including one die D1.

The composite substrate 100A includes a printed circuit board 30, a plurality of redistribution layers 10, a plurality of redistribution layers 40, a connecting layer 20 and a connecting layer 50. The redistribution layers 10 are disposed on the printed circuit board 30. The connecting layer 20 may be, for example, a low-loss sheet-like adhesive layer, which adheres the printed circuit board 30 and the redistribution layers 10 and is utilized to electrically connect the redistribution layers 10 and the printed circuit board 30. The die D1 is electrically connected to the redistribution layers 10. Although not shown in FIG. 2, in the communication device 1, the redistribution layers 10 respectively connected to multiple dies is the same redistribution layer 10 disposed in an integrated manner as shown in FIG. 1G.

The redistribution layers 40 are disposed on one side of the printed circuit board 30 away from the redistribution layers 10, and the antenna RA1 is disposed in the redistribution layers 40. The connecting layer 50 may be, for example, a low-loss sheet-like adhesive layer that adheres the printed circuit board 30 and the redistribution layers 40 and is utilized to electrically connect the redistribution layers 40 and the printed circuit board 30.

The die D1 is connected to the redistribution layer 10 through a plurality of solder bumps T1. Moreover, since the metal line width in the metal wiring layer 10M of the redistribution layer 10 is smaller, the size of the solder bump T1 may be smaller, and the diameter may fall within the range of 10 microns to 200 microns.

Moreover, when the signal RF is input from the signal input terminal in the communication device 1, the signal RF will reach the die D1 after passing through the metal wiring layer 10M and the solder bump T1 of the redistribution layer 10 in sequence, without passing through the printed circuit board 30 below the redistribution layer 10.

The roughness of the metal wiring layer 10M of the composite substrate 100A provided according to the embodiment of the present disclosure generally falls within the range of 0.2 microns to 0.7 microns. The ratio of the roughness of the copper wires of the printed circuit board 30 to the roughness of the metal wiring layer 10M generally falls within the range of 4.5 to 16.

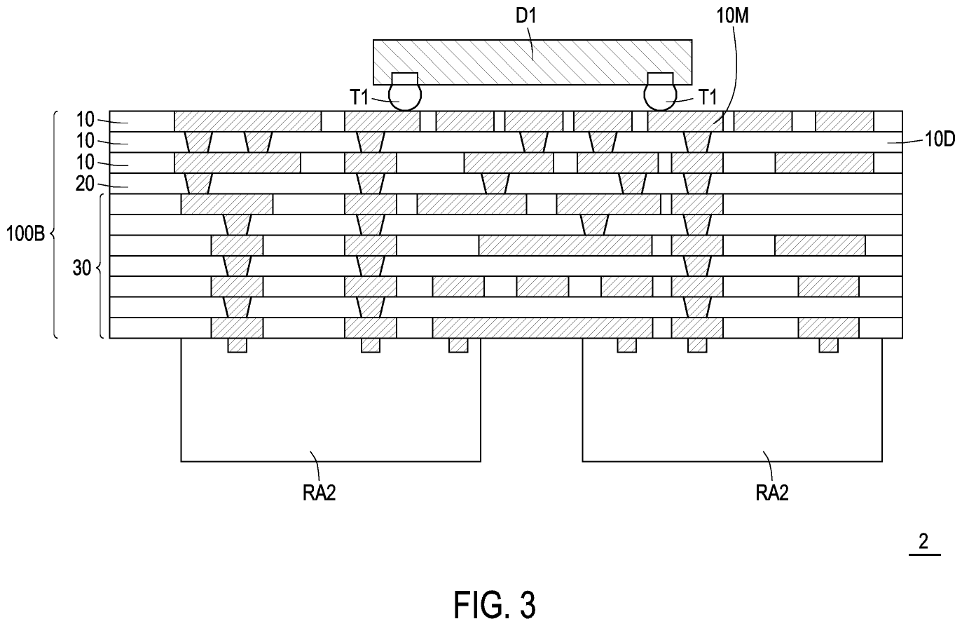

Referring to FIG. 3, according to an embodiment of the present disclosure, a communication device 2 is provided, including a plurality of dies, a composite substrate 100B and an antenna RA2. For the purpose of illustration, FIG. 3 only shows a partial structure of the communication device 2 including one die D1.

The composite substrate 100B includes a printed circuit board 30, a plurality of redistribution layers 10 and a connecting layer 20. The redistribution layers 10 are disposed on the printed circuit board 30. The connecting layer 20 may be, for example, a low-loss sheet-like adhesive layer, which adheres the printed circuit board 30 and the redistribution layers 10 and is utilized to electrically connect the redistribution layers 10 and the printed circuit board 30. The die D1 is electrically connected to the redistribution layers 10. Although not shown in FIG. 3, in the communication device 2, the redistribution layers 10 respectively connected to the dies is the same redistribution layer 10 disposed in an integrated manner as shown in FIG. 1G. The printed circuit board 30 is disposed between the antenna RA2 and the redistribution layer 10, and the antenna RA2 is electrically connected to the dies through the composite substrate 100B. According to an embodiment of the present disclosure, the antenna RA2 is a low-temperature co-fired ceramic antenna, but the present disclosure is not limited thereto.

The die D1 is connected to the redistribution layer 10 through a plurality of solder bumps T1. Moreover, since the metal line width in the metal wiring layer 10M of the redistribution layer 10 is smaller, the size of the solder bump T1 may be smaller, and the diameter may fall within the range of 10 microns to 200 microns.

In addition, when the signal RF is input from the signal input terminal in the communication device 2, the signal RF will reach the die D1 after passing through the metal wiring layer 10M of the redistribution layer 10 and the solder bump T1 in sequence, without passing through the printed circuit board 30 below the redistribution layer 10.

The roughness of the metal wiring layer 10M of the composite substrate 100B provided according to the embodiment of the present disclosure generally falls within the range of 0.2 microns to 0.7 microns. The ratio of the roughness of the copper wires of the printed circuit board 30 to the roughness of the metal wiring layer 10M generally falls within the range of 4.5 to 16.

It should also be noted that the composite substrate 100 and the composite substrates 100A and 100B in the communication devices 1 and 2 provided by the embodiment of the present disclosure may be implemented by replacing some layers of the printed circuit board 30 in the conventional communication device 3 with the redistribution layer 10 and the redistribution layer 40. Accordingly, the composite substrates 100, 100A, and 100B provided by the embodiments of the present disclosure are suitable for connecting multiple dies, and the dies do not need to be packaged, which significantly reduces the manufacturing cost of the communication devices 1 and 2.

In summary, the composite substrate provided by the embodiment of the present disclosure is suitable for connecting unpackaged dies, which significantly reduces the manufacturing cost of communication devices, and the transmission path of signals is effectively shortened, thereby reducing transmission loss. In addition, the transmission path of signals is on the redistribution layer with low DK and DF, the surface roughness of the metal wiring layer of the redistribution layer is low, which not only reduces transmission loss, but also reduces the difficulty in the design of input impedance matching.

What is claimed is:

1. A composite substrate adaptable for connecting a plurality of dies, and the composite substrate comprising:
a printed circuit board;
at least one first redistribution layer disposed on the printed circuit board; and
a first connecting layer disposed to electrically connect the at least one first redistribution layer and the printed circuit board,
wherein each of the plurality of dies is electrically connected to the at least one first redistribution layer, and is integrally disposed with the at least one first redistribution layer corresponding to each of the plurality of dies.

2. The composite substrate according to claim 1, wherein the first connecting layer comprises an adhesive.

3. The composite substrate according to claim 1, wherein the first connecting layer utilizes a hybrid bonding technology to connect the at least one first redistribution layer and the printed circuit board.

4. The composite substrate according to claim 1, wherein each of the plurality of dies is connected to the at least one first redistribution layer through a plurality of solder bumps, and the plurality of solder bumps are disposed between the corresponding die and the at least one first redistribution layer, and a diameter of each of the plurality of solder bumps falls within a range of 10 microns to 200 microns.

5. The composite substrate according to claim 4, wherein when a signal is input from a signal input terminal of the composite substrate, the signal does not pass through the printed circuit board, and reaches the corresponding die after passing through the at least one first redistribution layer and the solder bump.

6. The composite substrate according to claim 1, wherein the at least one first redistribution layer and the printed circuit board comprise a plurality of conductive lines, and a ratio of a roughness of the conductive line of the printed circuit board to a roughness of the conductive line of the at least one first redistribution layer falls within a range of 4.5 to 16.

7. The composite substrate according to claim 1, wherein the at least one first redistribution layer comprises a plurality of conductive lines, and a roughness of each of the plurality of conductive lines falls within a range of 0.2 microns to 0.7 microns.

8. The composite substrate according to claim 1, further comprising a second connecting layer and at least one second redistribution layer that are disposed on one side of the printed circuit board away from the at least one first redistribution layer, wherein the second connecting layer is disposed to electrically connect the at least one second redistribution layer and the printed circuit board.

9. The composite substrate according to claim 1, further comprising a through hole penetrating the first connecting layer, wherein the at least one first redistribution layer is electrically connected to the printed circuit board through the through hole.

10. The composite substrate according to claim 1, wherein the at least one first redistribution layer comprises a plurality of conductive lines, and line widths of the plurality of conductive lines corresponding to each of the plurality of dies are smaller than line widths of the plurality of conductive lines that do not correspond to each of the plurality of dies.

11. The composite substrate according to claim 10, wherein the line widths of the plurality of conductive lines corresponding to each of the plurality of dies fall within a range of 3 microns to 50 microns.

12. The composite substrate according to claim 1, wherein the printed circuit board comprises a through hole whose width is gradually increased in a stacking direction of the composite substrate, and the at least one first redistribution layer comprises a through hole whose width is gradually decreased in the stacking direction.

13. A communication device, comprising:
a plurality of dies;
a composite substrate comprising:
a printed circuit board;
at least one first redistribution layer disposed on the printed circuit board; and
a first connecting layer disposed to electrically connect the at least one first redistribution layer and the printed circuit board, wherein each of the plurality of dies is electrically connected to the at least one first redistribution layer, and is integrally disposed with the at least one first redistribution layer corresponding to each of the plurality of dies; and
at least one antenna, wherein the printed circuit board is disposed between the at least one antenna and the at least one first redistribution layer, and the at least one antenna is electrically connected to the plurality of dies through the composite substrate.

14. The communication device according to claim 13, wherein the first connecting layer is a sheet-like adhesive layer.

15. The communication device according to claim 13, wherein the at least one antenna is a low-temperature co-fired ceramic antenna.

16. The communication device according to claim 13, wherein the composite substrate further comprises at least a second redistribution layer and a second connecting layer, the at least one second redistribution layer is disposed on one side of the printed circuit board away from the at least one first redistribution layer, and the at least one antenna is disposed in the at least one second redistribution layer, the second connecting layer is disposed to electrically connect the at least one second redistribution layer and the printed circuit board.

17. The communication device according to claim 13, wherein each of the plurality of dies is connected to the at least one first redistribution layer through a plurality of solder bumps, and the plurality of solder bumps are disposed between the corresponding die and the at least one first redistribution layer, and a diameter of each of the plurality of solder bumps falls within a range of 10 microns to 200 microns.

18. The communication device according to claim 17, wherein when a signal is input from a signal input terminal of the composite substrate, the signal does not pass through the printed circuit board, and reaches the corresponding die after passing through the at least one first redistribution layer and the solder bump.

19. The communication device according to claim 13, wherein the at least one first redistribution layer and the printed circuit board comprise a plurality of conductive lines, and a ratio of a roughness of the conductive line of the printed circuit board to a roughness of the conductive line of the at least one first redistribution layer falls within a range of 4.5 to 16.

20. A manufacturing method of a composite substrate, comprising the following:
disposing a transparent substrate;
forming at least one redistribution layer on the transparent substrate;
disposing a connecting layer on the at least one redistribution layer;
disposing a printed circuit board on the connecting layer;
removing the transparent substrate to form a stacked structure;
forming a first metal layer on one side of the stacked structure close to the at least one redistribution layer, and forming a second metal layer on the other side of the stacked structure close to the printed circuit board;
forming a through hole in the stacked structure;
disposing a third metal layer on a sidewall of the through hole; and
performing photolithography and etching processes on the first metal layer and the second metal layer to form a first circuit layer and a second circuit layer respectively, wherein the first circuit layer and the second circuit layer are at least partially electrically connected to the third metal layer.
